(19) United States
(12) Patent Application Publication
(10) Pub. No.: US 2009/0011148 A1
(43) Pub. Date: Jan. 8, 2009

(54) Methods and apparatuses promoting adhesion of dielectric barrier film to copper

(75) Inventors: Nagarajan Rajagopalan, Santa Clara, CA (US); Bok Heon Kim, San Jose, CA (US); Lester A. D'Cruz, San Jose, CA (US); Zhenjiang Cui, San Jose, CA (US); Girish A. Dixit, San Jose, CA (US); Visweswaren Sivaramakrishnan, Santa Clara, CA (US); Hichem M'Saad, Santa Clara, CA (US); Meiyee Shek, Mountain View, CA (US); Li-Qun Xia, Santa Clara, CA (US)

Correspondence Address: TOWNSEND AND TOWNSEND AND CREW LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/214,393

(22) Filed: Jun. 17, 2008

Related U.S. Application Data
(62) Division of application No. 10/783,316, filed on Feb. 20, 2004.

(51) Int. Cl. C23C 16/22

(52) U.S. Cl. 427/577; 427/255.18; 427/579; 427/569

(57) ABSTRACT

Adhesion between a copper metallization layer and a dielectric barrier film may be promoted by stabilizing a flow of a silicon-containing precursor in a divert line leading to the chamber exhaust. The stabilized gas flow is then introduced to the processing chamber to precisely form a silicide layer over the copper. This silicidation step creates a network of strong Cu—Si bonds that prevent delamination of the barrier layer, while not substantially altering the sheet resistance and other electrical properties of the resulting metallization structure.

### BACKGROUND OF THE INVENTION

Due to its relatively low resistance and cost, copper is finding increasing use as a conductive layer in the interconnect metallization structures of integrated circuits and other semiconductor devices. FIGS. 1A-1E show simplified cross-sectional views of conventional steps for fabricating a damascene interconnect structure utilizing copper metallization.

In FIG. 1A, an interlayer dielectric (ILD) 100 is formed over a first conducting layer 102 and then patterned to create opening 104. While opening 104 is generically shown in FIG. 1A as a via hole, in dual damascene approaches the opening can take the more complex form of a trench overlying a narrower via hole.

In FIG. 1B, a first barrier layer 106 is formed within opening 104 and over patterned ILD 100. Barrier layer 106 may be formed from a variety of materials, including but not limited to SiN, TiN, Ta, TaN, Ta/TaN, as well as the barrier low k (BLOK®) material manufactured by Applied Materials, Inc. of Santa Clara, Calif. The primary function of the barrier layer is to block diffusion of copper of the metallization structure. ILD 100 and barrier layer 106 may be formed by such techniques such as chemical vapor deposition, as performed by the PRODUCER® tool manufactured by Applied Materials, Inc. of Santa Clara, Calif.

In FIG. 1C, copper metal interconnect 108 is formed over first barrier layer 106, within opening 104 and over the top of ILD layer 100. The copper metal 108 may be formed by such techniques as electroplating, for example as is performed by the ELECTRA CU™ tool manufactured by Applied Materials, Inc. of Santa Clara, Calif.

In FIG. 1D, the wafer is removed from the electroplating device and transferred to a chemical mechanical polishing tool for removal of copper metal 108 and barrier layer 106 outside of the now-filled opening in ILD 100, resulting in the formation of conducting copper via structure 110. In FIG. 1E, the wafer is transferred from the chemical mechanical polishing module to a chemical vapor deposition (CVD) module for formation of second barrier layer 112 over copper via 110. The function of second barrier layer 112 to block any upward diffusion of copper metal from the via into successive dielectric layers of the interconnect structure.

The process sequence shown and described above in connection with FIGS. 1A-1E can be repeated to form additional metallization layers overlying and in contact with copper via 110.

The process flow just shown and described is somewhat simplified. For example, FIGS. 1CA-CC show detailed and enlarged views of the fabrication steps leading up to creation of the copper via shown in FIG. 1D. Specifically, removal of excess copper metal during the CMP step shown in FIG. 1C may be performed under oxidizing conditions. Thus, as shown in FIG. 1CB, at the conclusion of the CMP step and prior to formation of the second barrier layer, a thin copper oxide layer 114 typically overlies copper via plug 110. Formation of such a copper oxide layer is not necessarily the result of CMP performed under oxidizing conditions, and copper oxide may also result from exposing the processed wafer to air, as may occur during transfer of the wafer between different processing tools.

Because this copper oxide layer 114 is a dielectric material, it can degrade the conductive properties of the interconnect metallization Therefore, as shown in FIG. 1 CC, the metallization layer may be exposed to a reactive ionized species from a plasma to remove the copper oxide prior to formation of the top barrier layer and additional portions of the interconnect structure. The oxide removal plasma may be generated in gases such as NH₃ mixed with a carrier gas comprising N₂. The oxide removal plasma may be generated remote from the chamber or generated within the chamber. This plasma exposure may take place in the same chamber in which the upper barrier layer is subsequently deposited. Methods and apparatuses for removing copper oxide are described in detail in U.S. Pat. No. 6,365,518, coassigned with the present invention and hereby incorporated by reference for all purposes.

The character of the interface between the Cu and the dielectric barrier film is important to ensure reliability of devices utilizing the metallization structure. Properties such as stress migration, electro-migration, and time dependent dielectric breakdown (TDDB) depend upon the quality of the interface between the Cu and dielectric barrier film.

Stress migration and electro-migration are affected by the interface diffusion of Cu atoms along the Cu/barrier interface. The interface diffusion is dependent on the nature of the interface chemistry and the adhesion energy between the layers. If adhesion energy between Cu and the barrier film is strong, reduced unwanted Cu electromigration will result.

Another issue associated with interface between the Cu and the dielectric barrier film is lack of adhesion. Specifically, copper does not generally exhibit strong affinity with carbon or nitrogen, typical components of dielectric barrier films. Thus, under certain conditions, the dielectric barrier layer may undesirably delaminate and become separated from the copper, disrupting electronic performance of the metallization structure.

Conventional approaches to improving adhesion between a copper metal and an overlying dielectric diffusion barrier have included the formation of a silicide layer intervening between the copper and the overlying dielectric. However, introduction of such a silicide layer offers a number of potential problems.

First, the presence of the silicide layer can adversely increase electrical resistance exhibited by the copper. Specifically, although the solid solubility of Si in Cu is high, the Si can elevate sheet resistance of Cu. This change in sheet resistance can in turn deleteriously reduce the speed exhibited by a device incorporating the metallization layer.

In addition, silicon within the copper can form intermetallic compounds like CuSi and CuSi₂. The compounds can also increase the resistivity and thereby reduce reliability and yield of the device.

Therefore, there is a need in the art for methods and apparatuses for forming copper metallization structures including dielectric barrier films exhibiting strong adhesion to copper layers.

### BRIEF SUMMARY OF THE INVENTION

Adhesion between copper and an overlying dielectric diffusion barrier may be promoted by precise formation of a thin silicide layer over the copper prior to deposition of the dielectric. A material delivery system is configured to stabilize a flowed silicon-containing precursor through a divert pathway bypassing the processing chamber, while other processing gases are flowed into the processing chamber to stabilize the environment therein. Once the velocity of flow of silicon-containing precursor has been stabilized in the divert pathway, the silicon-containing precursor is introduced into the processing chamber to form the silicide layer under extremely precise conditions. In certain embodiments, stabilization in flow of silicon-containing precursor may allow formation of a thin, high quality silicide film exhibiting sufficient density to serve as a diffusion barrier, thereby obviating the need to form a separate overlying diffusion barrier.

An embodiment of a method in accordance with the present invention for preparing a metal surface for formation of a dielectric barrier layer, comprises, providing within a processing chamber a substrate bearing a copper layer, and stabilizing a flow rate of a silicon-containing precursor flowed to an exhaust of the processing chamber. A processing gas is flowed into the processing chamber while the flow of the silicon-containing precursor is stabilized. The stable silicon-containing precursor is flowed into the processing chamber to react with the processing gas to form a silicide layer over the copper layer.

An embodiment of a gas supply panel in accordance with the present invention, comprises, a first mass flow controller configured to be in fluid communication with a processing gas source through a first inlet, and a delivery line configured to be in fluid communication with the first mass flow controller and with a processing chamber through a first outlet. A second mass flow controller is configured be in fluid communication with a source of silicon-containing precursor through a second inlet, and a divert line is configured to be in fluid communication with the second mass flow controller and with a chamber exhaust through a second outlet. A divert valve is configured to selectively place the second mass flow controller in fluid communication with the delivery line or with the divert line.

An embodiment of a substrate processing apparatus in accordance with the present invention, comprises, a processing chamber including an exhaust, and a gas distribution system configured to receive and deliver gases to a gas distribution face plate located proximate to a substrate support within the processing chamber. A gas supply panel comprises a first mass flow controller configured to be in fluid communication with a processing gas source through a first inlet, and a delivery line configured to be in fluid communication with the first mass flow controller and with a first outlet. A second mass flow controller is configured be in fluid communication with a source of silicon-containing precursor through a second inlet. A divert line configured to be in fluid communication with the second mass flow controller and with a second outlet, and a divert valve is configured to selectively place the second mass flow controller in fluid communication with the delivery line or with the divert line. A first conduit links the first outlet with the processing chamber, and a second conduit links the second outlet with the processing chamber exhaust.

A further understanding of embodiments in accordance with the present invention can be made by way of reference to the ensuing detailed description taken in conjunction with the accompanying drawings.

### BRIEF DESCRIPTION OF THE DRAWINGS

FIGS. 1A-E show simplified cross-sectional views of steps of a conventional process flow for forming a copper Damascene interconnect structure.

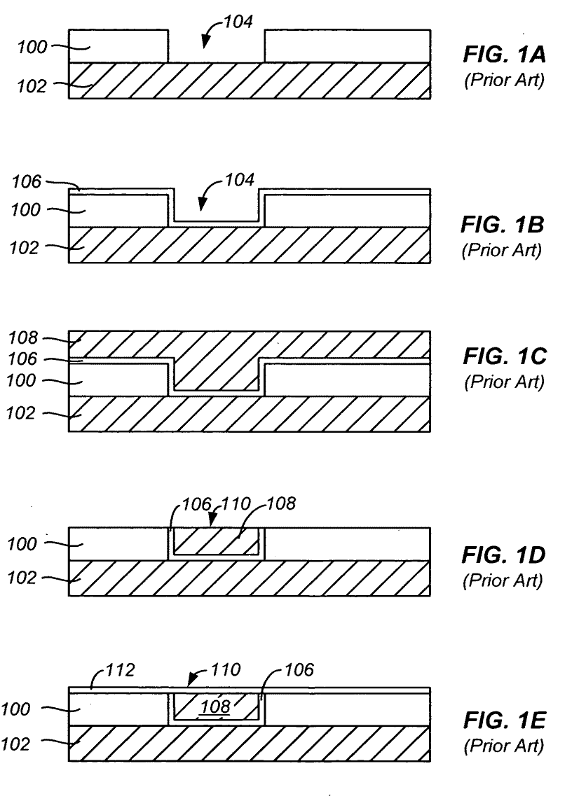

FIGS. 1CA-1CC show detailed, enlarged cross-sectional views of certain of the steps of the conventional process flow shown in FIGS. 1A-1E.

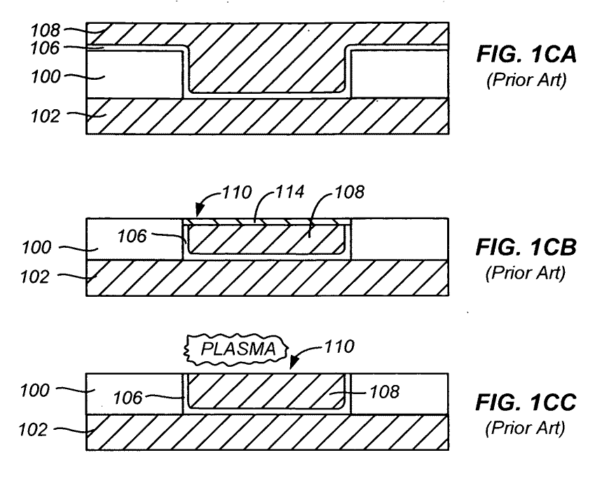

FIG. 2 is a simplified flow chart illustrating a process in accordance with one embodiment of the present invention.

FIG. 3 presents a recipe for one embodiment of a series of process flows in accordance with the present invention.

FIG. 4 is a bar graph showing energy of adhesion between an underlying copper layer and overlying SiN dielectric barrier layers formed under a variety of conditions.

FIG. 5 plots percent change in sheet resistance exhibited by copper-bearing wafers exposed to various processing conditions.

FIG. 6 shows a simplified cross-sectional view of one embodiment of a PECVD apparatus in accordance with the present invention.

FIG. 7 shows a schematic view of the gas delivery system of the PECVD system shown in FIG. 6.

FIG. 8 is a bar graph showing percentage shift in sheet resistance for copper layers exposed to silane under various conditions.

### DETAILED DESCRIPTION OF THE INVENTION

Embodiments in accordance with the present invention promote adhesion between a copper metallization layer and an overlying dielectric by formation of an intervening silicide layer under carefully controlled conditions. Formation of such a silicide layer prior to creation of a dielectric layer produces a network of strong Cu—Si bonds that prevent delamination of the barrier layer, while not substantially altering sheet resistance and other electrical properties exhibited by the metallization.

The desired silicidation can be achieved by deliberately introducing Si-containing precursor on top of Cu for a brief time in a highly controlled fashion, such that the Si-containing precursor is allowed to react thermally with Cu to form a strong chemical bond across the interface before dielectric deposition.

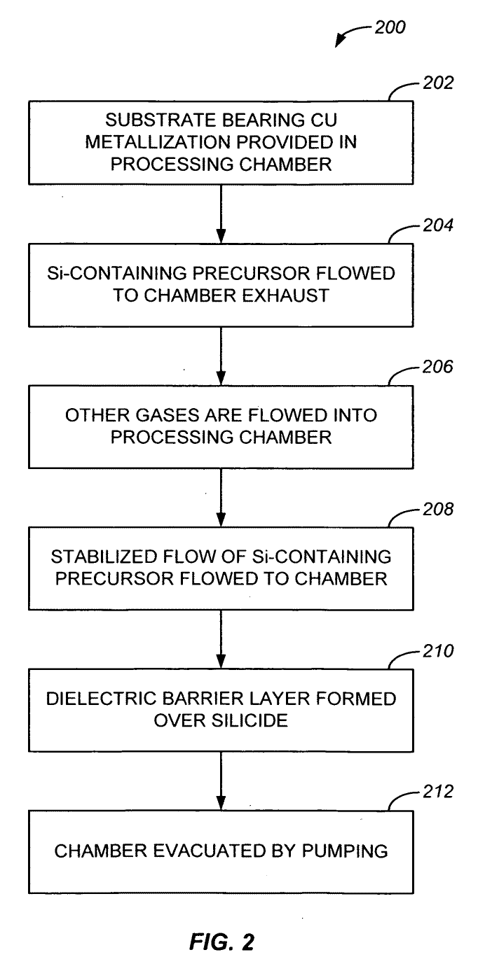

FIG. 2 is a simplified flow chart illustrating steps of a process in accordance with an embodiment of the present invention, for promoting adhesion between a copper layer and an overlying dielectric diffusion barrier layer. In first step 202 of process 200, a substrate bearing a Cu metallization layer is provided in a processing chamber.

In second step 204, a silicon-containing precursor is flowed from a source directly to the chamber exhaust through a divert pathway. During this divert step, the flow of silicon-containing precursor is stabilized.

In third step 206, while the silicon-containing precursor is flowed directly into the chamber exhaust, other gases necessary for forming the barrier layer are flowed into the processing chamber to stabilize the chamber pressure. Such flowed gases include carrier gases and a gas reactive with the silicon-containing precursor to form a dielectric barrier film.

In fourth step 208, the stabilized flow of silicon-containing precursor material is redirected and introduced into the processing chamber. The silicon-containing precursor gas reacts with the copper layer and forms a thin layer of silicide material having a precise thickness.

In fifth step 210, a combination of materials including the Si-containing precursor is flowed into the chamber to form a dielectric layer on top of the silicide. In sixth step 212, at the conclusion of the dielectric deposition process, gases and chemical species remaining in the chamber are evacuated by pumping.

Embodiments of the invention may be performed in the processing chamber of any suitable processing apparatus, such as the PRODUCERS plasma enhanced chemical vapor deposition (PECVD) apparatus manufactured by Applied Materials Inc., of Santa Clara, Calif. In a PECVD apparatus, process gases are excited and/or dissociated by the application of energy such as radio frequency (RF) energy to form a plasma. The plasma contains ions of the processing gases, and reacts at the substrate surface to form the deposited material layer.

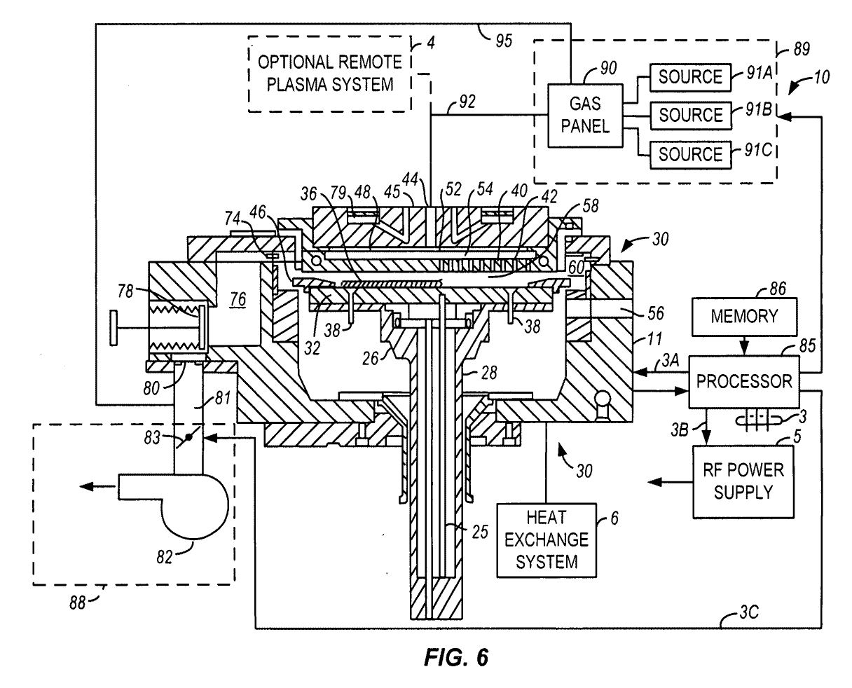

An example of a PECVD apparatus is shown in cross-section in FIG. 6. FIG. 6 shows a system 10 including a processing chamber 30, a vacuum system 88, a gas delivery system 89, an RF power supply 5, a heat exchanger system 6, a substrate pedestal/heater 32 and a processor 85 among other major components. A gas distribution manifold (also referred to as an inlet manifold, a face plate, or “showerhead”) 40 introduces process gases supplied from the gas delivery system 89 into a reaction zone 58 of the processing chamber 30. The heat exchange system 6 may employ a liquid heat exchange medium, such as water or a water-glycol mixture, to remove heat from the processing chamber 30 and maintain certain portions of the processing chamber 30 at a suitable temperature.

The gas delivery system 89 delivers gases to the processing chamber 30 via gas line 92. Gas delivery system 89 includes a gas supply panel 90 and gas or liquid or solid sources 91A-C (additional sources may be added if desired), containing gases (such as SiH₄, ozone, halogenated gases, or N₂) or liquids (such as TEOS) or solids. The gas supply panel 90 has a mixing system that receives the process gases and carrier gases (or vaporized liquids) from the sources 91A-C. Process gases may be mixed and sent to a central gas inlet 44 in a gas feed cover plate 45 via the supply line 92 (other lines may be present, but are not shown).

Process gas is injected into processing chamber 30 through the central gas inlet 44 in the gas-feed cover plate 45 to a first disk-shaped space 48. Heat exchanger passages 79 may be provided in the cover plate 45 to maintain the cover plate 45 at a desired temperature. The process gas passes through passageways (not shown) in a baffle plate (or gas blocker plate) 52 to a second disk-shaped space 54 and then to the showerhead 40. The showerhead 40 includes a large number of holes or passageways 42 for supplying the process gas into reaction zone 58. Process gas passes from the holes 42 in the showerhead 40 into the reaction zone 58 between the showerhead 40 and the pedestal 32. Once in the reaction zone 58, the process gas reacts on the wafer 36. Byproducts of the reaction then flow radially outward across the edge of the wafer 36 and a flow restrictor ring 46, which is disposed on the upper periphery of pedestal 32. Then, the process gas flows through a choke aperture formed between the bottom of an annular isolator and the top of chamber wall liner assembly 53 into a pumping channel 60.

The vacuum system 88 maintains a specified pressure in the process chamber 30 and removes gaseous byproducts and spent gases from the process chamber 30. The vacuum system 88 includes a vacuum pump 82 and a throttle valve 83. Upon entering the pumping channel 60, the exhaust gas is routed around the perimeter of the processing chamber 30, and is evacuated by a vacuum pump 82. The pumping channel 60 is connected through the exhaust aperture 74 to a pumping plenum 76. The exhaust aperture 74 restricts the flow between the pumping channel 60 and the pumping plenum 76. A valve 78 gates the exhaust through an exhaust vent 80 and foreline 81 to the vacuum pump 82.

The pedestal 32 may be made of ceramic and may include an embedded RF electrode (not shown), such as an embedded molybdenum mesh. A heating element such as a resistive heating element (e.g., an embedded molybdenum wire coil) or a coil containing a heating fluid may also be in the pedestal 32. Alternatively or additionally, a cooling element (not shown) may be included in the pedestal 32. The pedestal 32 may be made from aluminum nitride and is preferably diffusion bonded to a ceramic support stem 26 that is secured to a water cooled aluminum shaft 28 that engages a lift motor (not shown). The ceramic support stem 26 and the aluminum shaft 28 have a central passage that is occupied by a nickel rod 25 that transmits low frequency RF power to the embedded electrode.

The pedestal 32 may support the wafer 36 in a wafer pocket 34 when the wafer 36 is on the pedestal 32. The pedestal 32 may move vertically and may be positioned at any suitable vertical position. For example, when the pedestal 32 is in a lower loading position (slightly lower than at slit valve 56), a robot blade (not shown) in cooperation with the lift pins 38 and a lifting ring transfers the wafer 36 in and out of chamber 30 through a slit valve 56. The slit valve 56 vacuum-seals the processing chamber 30 to prevent the flow of gas into or out of the processing chamber 30. When the pedestal 32 is disposed in a lower position, the lift pins 38 (which may be stationary) support the wafer 36. The robot blade (not shown) used to transfer the wafer 36 into the chamber is withdrawn. The wafer 36 may remain on the lift pins 38 so that the wafer 36 can be processed according to the first process. The pedestal 32 may rise to raise the wafer 36 off the lift pins 38 onto the upper surface of the pedestal 32 so that the wafer 36 can be heated to a second temperature suitable for a second process. The pedestal 32 may further raise the wafer 36 so that the wafer 36 is any suitable distance from the gas distribution manifold 40.

Motors and optical sensors (not shown) may be used to move and determine the position of movable mechanical assemblies such as the throttle valve 83 and the pedestal 32. Bellows (not shown) attached to the bottom of the pedestal 32 and the chamber body 11 form a movable gas-tight seal around the pedestal 32. The processor 85 controls the pedestal lift system, motors, gate valve, plasma system, and other system components over control lines 3 and 3A-C. The processor 85 may execute computer code for controlling the apparatus. A memory 86 coupled to the processor 85 may store the computer code. The processor 85 may also control a remote plasma system 4. In some embodiments, the remote plasma system 4 may include a microwave source and may be used to form a plasma that can be used to clean the process chamber 30 or process the wafer 36. Computer code may be used to control chamber components that may be used to load the wafer 36 onto the pedestal 32, lift the wafer 36 to a desired height in the chamber 30, control the spacing between the wafer 36 and the showerhead 40, and keep the lift pins 38 above the upper surface of the pedestal 32.

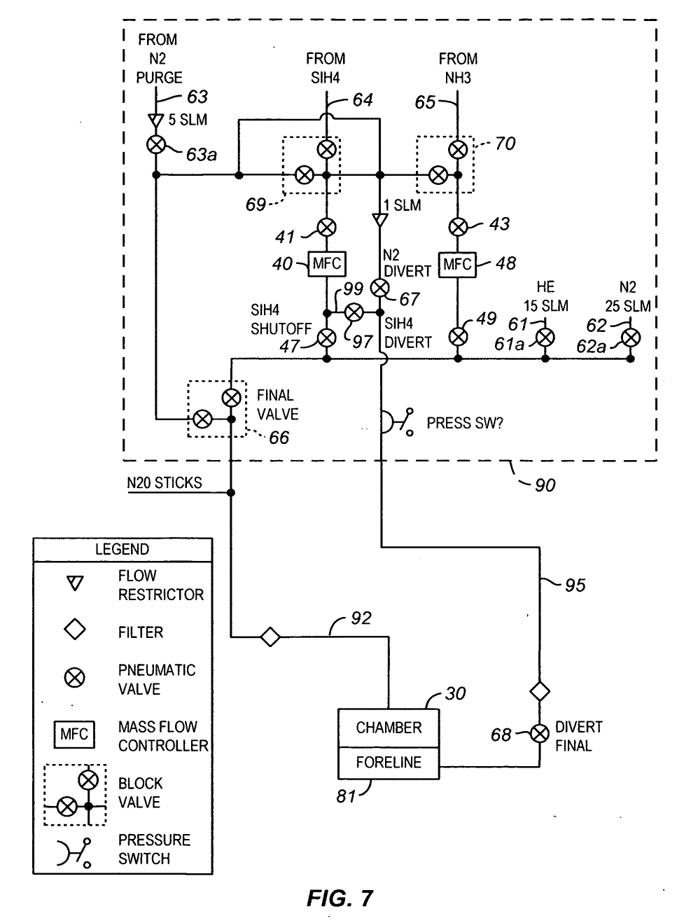

FIG. 7 shows a schematic diagram of gas supply panel in accordance with one embodiment of the present invention, for use with the PECVD chamber just described. Gas supply panel 90 comprises first inlet 61, second inlet 62, third inlet 63, fourth inlet 64, and fifth inlet 65. First and second inlets 61 and 62 are configured to receive a flow of a processing gas through valves 61a and 62a, respectively, and to flow these processing gas through block final valve 66 into processing chamber 30. Examples of such processing gases include helium and nitrogen.

Gas supply panel 90 is configured to receive a purge gas such as nitrogen through inlet 63 and valve 63a, and to convey this purge gas to block final valve 66. Third inlet 63 is also in selective fluid communication with foreline 81 of processing chamber 30 through divert valve 67, divert line 95, and final divert valve 68. Third inlet 63 is further in fluid communication with first block injection valve 69, and with second block injection valve 70.

First injection valve 69 is configured to receive a flow of a silicon-containing precursor material, such as silane, from fourth inlet 64. The flow of purge gas through first injection valve 69 carries the silicon-containing precursor material therein. This silicon-containing precursor material is carried by the purge gas to mass flow controller 40 through valve 41, from mass flow controller 40 through shutoff valve 47 to block final valve 66, and then to chamber 30.

Similarly, second injection valve 70 is configured to receive a flow of another processing material, for example ammonia, from fifth inlet 65. This processing material is also injected into the purge gas flowing through second injection valve 70, and is carried into chamber by successive flow through valve 43, mass flow controller 48, shutoff valve 49, and block final valve 66.

As previously described, embodiments of apparatuses and methods in accordance with the present invention allow introduction of silicon-containing precursor material into a processing chamber under highly controlled conditions, to form a silicide layer having an extremely precise thickness. To accomplish this goal, it is important to establish a stable environment within the processing chamber, and then to introduce the silicon-containing precursor material in as controlled a manner as possible.

To this end, gas supply panel 90 of FIG. 7 includes divert branch 99 and associated shunt valve 97 positioned downstream of mass flow controller 90. Initially, shunt valve 97 is configurable in a first state to place the flow of purge gas from valve 69 and mass flow controller 40 in fluid communication with the divert line 95. Thus during an initial process stage, shutoff valve 47 is closed, and shunt valve 97 is opened. The rate of silane flowing through mass flow controller 40 is stabilized while being prevented from entering the processing chamber.

The configuration of shunt valve 97 and divert branch 99 does not affect the flow of material through other portions of gas supply panel 90. Thus while the vaporized silicon-containing precursor flow is being stabilized, gas supply panel 90 allows other materials involved in forming the silicide, for example ammonia, to be flowed into the processing chamber. This allows the environment within the processing chamber to be stabilized prior to initiation of the silicide-forming reaction.

In a subsequent process stage, shunt valve 97 is configurable in a second state to place the flow of purge gas into fluid communication with the chamber. Thus once the flow rate of silane has stabilized, shunt valve 97 is closed and shutoff valve 47 opened. The silane flowing through mass flow controller 40 is directed into the processing chamber 30 through final block valve 66 along with other gases NH₃ and N₂. This allows thermal reaction between the silane and Cu substrate located in the processing chamber, to form the controlled silicide layer.

The structure of the gas supply panel shown in FIG. 7 may be contrasted with that of a conventional gas supply panel. Specifically, conventional gas supply panel architectures feature a divert line that is positioned downstream of the final valve. Such architectures allow diversion of the silane during flow stabilization. However, they require that all other processing gases also be diverted into the chamber foreline during this process, precluding a flow of gases into the chamber to stabilize the environment therein.

In accordance with embodiments of the present invention, however, silane flowing through the divert branch is initially stabilized and discarded directly into the chamber foreline, while nonreacting gases such as NH₃, N₂, and He are introduced into the chamber to treat and remove CuO from the substrate. Once the flow of silane is stabilized and the CuO removal is complete by an adequate exposure of NH₃ and N₂ plasma, it is switched from divert branch 95 to join the flow of the other materials into the processing chamber, resulting in silicidation of Cu in a highly controlled fashion.

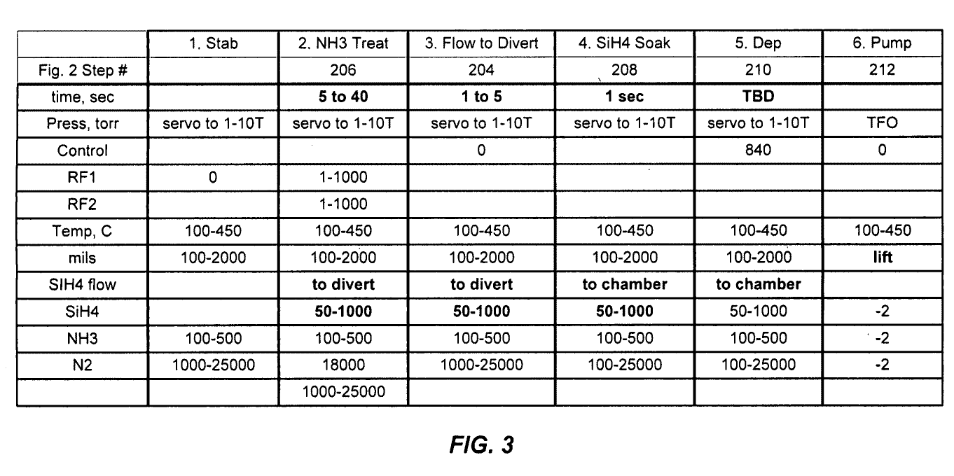

FIG. 3 presents one process recipe in tabular form for the various steps for forming a silicide layer utilizing the PRODUCER SE tool, over copper features patterned on a 300 mm diameter wafer in accordance with one embodiment of the present invention. FIG. 3 shows the changed state of the divert valve between steps 212 and 214 of FIG. 2.

FIG. 7 illustrates only one possible embodiment of a gas supply panel for use in accordance with the present invention. Thus while the specific gas supply panel shown in FIG. 7 features a divert valve and a separate shutoff valve, this is not required by the present invention. In accordance with alternative embodiments, the divert valve could operate as a three-way valve, allowing material inlet through one branch to flow either to the divert line or to the delivery line. Such an alternative embodiment would simplify the mechanical design of the apparatus, but could result in undesirable condensation of silane in the dead-ended branch. Such condensed material could subsequently be ejected onto the wafer and result in contamination.

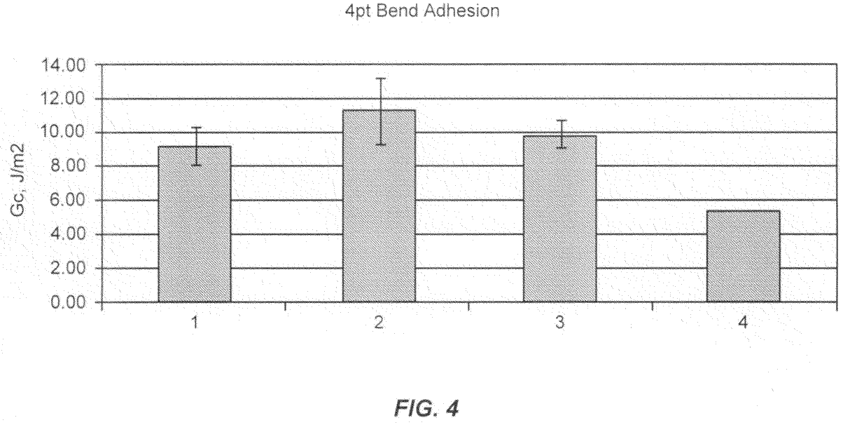

FIG. 4 is a bar chart illustrating adhesion energies resulting from various SiN deposition processes with different NH₃ treatment (for CuO removal) and with controlled silicidation. The adhesion energies reflected in FIG. 4 were measured using four point bend technique.

Deposition of dielectric under the first set of conditions took place after treating the Cu surface with pure NH₃ and N₂ gas with the silane gas for one second in a single-frequency deposition chamber. Dielectric deposition under the second set of conditions took place after treating the Cu surface with pure NH₃ gas with the silane gas for one second in a multi-frequency deposition chamber. Deposition of dielectric under the third set of conditions took place after treating the Cu surface with NH₃ gas diluted with nitrogen. Deposition of dielectric under the fourth set of conditions took place without any exposure to silane gas. FIG. 4 indicates that exposing the copper to silane promoted an approximate two-fold increase in energy of adhesion, as compared to the process lacking such silane exposure.

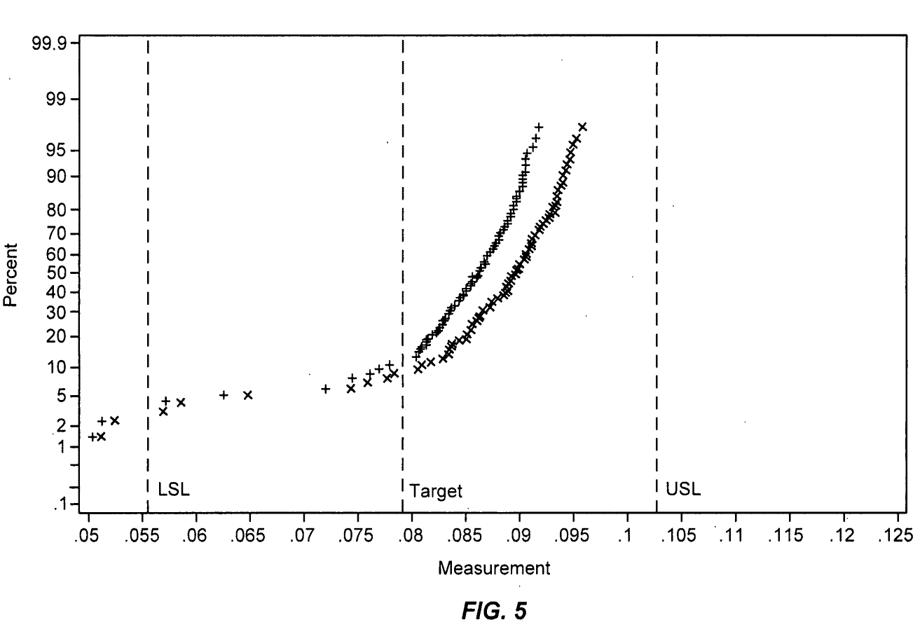

Treatment of the copper under extremely carefully controlled conditions is important to maintain the desirable electrical properties of the copper. FIG. 5 is a bar chart illustrating the percentage shift in sheet resistance (Rs) exhibited by copper exposed to silane under a variety of conditions. Specifically, for examples 1-4 of FIG. 5, the copper was exposed for one second to silane flow rates of 175 sccm, 200 sccm, 225 sccm, and 250 sccm, respectively, following treatment of the copper with pure or dilute ammonia to remove the copper oxide. FIG. 5 indicates an undesirable steady increase in sheet resistance resulting from exposure to increased silane. Therefore, in accordance with embodiments of the present invention, it is important that the velocity of the vaporized silane be stabilized before chamber introduction, and carefully controlled during chamber introduction.

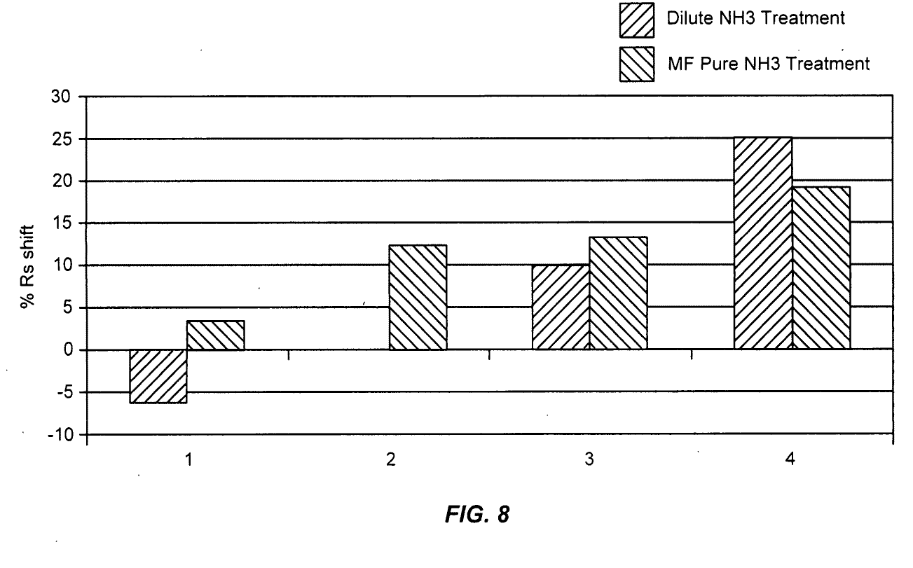

The shift in sheet resistance illustrated in FIG. 5 may be dependent upon the form of the underlying copper. FIG. 8 plots percent change in sheet resistance (Rs) for two different types of underlying copper structures. A first wafer bore a Cu seed blanket layer having a thickness of 1.2 kÅ. A second wafer bore a pattern of 5μ×5μ copper traces having a thickness of 2 kÅ. Both wafer types were exposed to silane flowed at 250 sccm for 1 second. The results are summarized in the following TABLE.

TABLE

| RECIPE | % SHIFT IN SHEET RESISTANCE | |
|---|---|---|
| wafer type | 1.2 kÅ Cu Seed Blanket | 2 kÅ Cu Patterned Traces |
| Dilute NH₃ | 25 | 4.1 |
| Pure NH₃ | 19 | 5.0 |

This indicates that the shift in sheet resistance of silicided copper shown in the TABLE and FIG. 5, may depend upon the form of the underlying copper.

Fabrication processes utilizing formation of a silicide layer are expected to show better device reliability and yield over corresponding processes lacking silicidation. Similar silicide films can be used to enhance adhesion of other dielectric barrier films like Blok, silicon carbide, and Advanced Blok.

While the above-described experimental results were obtained utilizing a Applied Materials PRODUCER® system. As a person of ordinary skill in the art would understand however, techniques for forming barrier layers over copper in accordance with embodiments of the present invention are not limited to this particular apparatus, and could be employed in conjunction with other systems.

And while the above-described examples relate to controlling the introduction of a stabilized flow of silane into the deposition chamber, the present invention is not limited to this particular application. Alternative embodiments in accordance with the present invention may control the introduction of other silicon-containing precursors, including but not limited to tri-methyl silane (TMS) and dimethyl phenyl silane (DMPS).

To summarize: utilizing the techniques of the present invention, adhesion between a copper metallization layer and an overlying dielectric material may be enhanced. In accordance with one embodiment of the present invention, adhesion may be promoted by forming a thin silicide layer over the copper prior to dielectric deposition, utilizing a divert line to stabilize the flow of silicon-containing precursor into the chamber exhaust while other reactants are flowed into the processing chamber to stabilize the environment therein.

The above description is illustrative and not restrictive, and as such the process parameters listed above should not be limiting to the claims as described herein. For example, the various techniques employed for promoting adhesion are separate and distinct, and thus it should be recognized that they may be employed alone or in various combinations to promote the formation of copper/dielectric interfaces exhibiting desirable properties.

And while the above discussion has focused upon the promotion of adhesion during the formation of copper metallization layers utilized in the formation of damascene interconnect structures, the present invention is not limited to this particular type of metallization material or application. Rather, embodiments in accordance with the present invention are generally applicable to controlling the microstructure of other metals utilized in other metallization schemes.

The scope of the invention may be determined with reference to the above description and to the appended claims, along with their full scope of equivalents.

1. A method of preparing a metal surface for formation of a dielectric barrier layer, the method comprising:
providing within a processing chamber a substrate bearing a copper layer;
stabilizing a flow rate of a silicon-containing precursor flowed to an exhaust of the processing chamber;
flowing a processing gas into the processing chamber while the flow of the silicon-containing precursor is stabilized; and
flowing the stable silicon-containing precursor into the processing chamber to react with the processing gas to form a silicide layer over the copper layer.

2. The method of claim 1 wherein:
stabilizing a flow rate of a silicon precursor comprises stabilizing a flow of silane; and
flowing the processing gas comprises flowing ammonia.

3. The method of claim 2 wherein flowing the processing gas comprises flowing ammonia mixed with nitrogen.

4. The method of claim 1 wherein the silicon-containing precursor and the processing gas are flowed through a common gas supply panel.

5. The method of claim 4 wherein the silicon-containing precursor is flowed to the chamber exhaust through a divert line.

6. The method of claim 1 further comprising forming a dielectric barrier layer over the silicide layer.

7. The method of claim 6 wherein forming the dielectric barrier layer comprises introducing a plasma within the processing chamber.

8. The method of claim 6 wherein forming the dielectric barrier layer comprises depositing a barrier layer selected from the group consisting of SiCN, oxygen doped SiC, SiN, TiN, Ta, TaN, Ta/TaN, BLOK®, and Black Diamond®.

9. The method of claim 1 wherein stabilizing the flow rate of the silicon-containing precursor comprises stabilizing the flow of one of silane, tri-methyl silane (TMS), and dimethyl phenyl silane (DMPS).

10-19. (canceled)
